(19) United States
(12) Patent Application Publication
(10) Pub. No.: US 2023/0038603 A1
(43) Pub. Date: Feb. 9, 2023

(54) SEMICONDUCTOR PACKAGE AND METHOD OF MANUFACTURING THE SAME

(71) Applicant: SAMSUNG ELECTRONICS CO., LTD., SUWON-SI (KR)

(72) Inventors: Juil Choi, Seongnam-si (KR); Unbyoung Kang, Hwaseong-si (KR); Sechul Park, Bucheon-si (KR); Hyojin Yun, Suwon-si (KR); Teahwa Jeong, Hwaseong-si (KR); Atsushi Fujisaki, Seongnam-si (KR)

(21) Appl. No.: 17/810,036

(22) Filed: Jun. 30, 2022

(30) Foreign Application Priority Data
Aug. 9, 2021 (KR) 10-2021-0104418

(51) Int. Cl. H01L 23/00; H01L 21/66

(52) U.S. Cl. CPC H01L 24/08; H01L 22/32; H01L 24/05; H01L 24/06; H01L 2224/0603; H01L 2224/05166; H01L 2224/05557; H01L 2224/05624; H01L 2224/05647; H01L 2224/08225; H01L 2224/08505

(57) ABSTRACT

A semiconductor package includes a semiconductor chip including a second bonding insulating layer surrounding at least a portion of each of a first bonding pad structure and a second bonding pad structure, in which the first bonding pad structure includes a first contact portion, a first bonding pad, and a first seed layer disposed between the first bonding pad and the first contact portion and extending in a first direction, the second bonding pad structure includes a second contact portion, a second bonding pad, and a second seed layer disposed between the second bonding pad and the second contact portion and extending in the first direction, and the second bonding insulating layer is in contact with a side surface of each of the first and second seed layers and the first and second bonding pads.

### CROSS-REFERENCE TO RELATED APPLICATION(S)

This application claims priority under 35 U.S.C. § 119 to Korean Patent Application No. 10-2021-0104418, filed on Aug. 9, 2021, in the Korean Intellectual Property Office, the disclosure of which is incorporated by reference herein in its entirety.

### TECHNICAL FIELD

The present inventive concept relates to a semiconductor package and method of manufacturing the same.

### DISCUSSION OF RELATED ART

In accordance with the trend for miniaturization and high performance of semiconductor packages, system-in-package (SIP) technology, in which a plurality of semiconductor chips performing different functions are embedded in a single package, has rapidly evolved as a high volume technology with wide ranging impact on electronics markets, for example, the market of portable consumer electronics. Here, an electrical die sorting (EDS) test is performed on each of the semiconductor chips. A semiconductor package formed with the SIP technology may include an EDS test pad. During the EDS test, a surface of the EDS test pad may be deformed (e.g., pile-up), so the use of the EDS test pad may be limited.

### SUMMARY

Embodiments of the present inventive concept provide a semiconductor package having enhanced heat dissipation characteristics using a test pad.

According to an embodiment of the present inventive concept, a semiconductor package includes: a base structure including a body having a rear surface on which a dummy pad and a connection pad are arranged and a rear insulating layer disposed on the rear surface and surrounding the dummy pad and the connection pad; and a semiconductor chip disposed on the base structure and including a semiconductor layer having a front surface facing the rear surface of the body, a test pad and an input/output pad disposed on the front surface of the semiconductor layer, a first bonding insulating layer surrounding the test pad and the input/output pad, a first bonding pad structure disposed between the test pad and the dummy pad, a second bonding pad structure disposed between the input/output pad and the connection pad, and a second bonding insulating layer disposed on the first bonding insulating layer and surrounding at least a portion of each of the first bonding pad structure and the second bonding pad structure, in which the first bonding pad structure includes a first contact portion being in contact with the test pad inside the first bonding insulating layer and having a lower surface positioned opposite to the test pad, a first bonding pad bonded to the dummy pad, and a first seed layer disposed between the first bonding pad and the first contact portion and extending in a first direction, parallel to the lower surface of the first contact portion, the second bonding pad structure includes a second contact portion being in contact with the input/output pad inside the first bonding insulating layer and having a lower surface positioned opposite to the input/output pad, a second bonding pad bonded to the connection pad, and a second seed layer disposed between the second bonding pad and the second contact portion and extending in the first direction, and the second bonding insulating layer is in contact with a side surface of each of the first and second seed layers and the first and second bonding pads.

According to an embodiment of the present inventive concept, a semiconductor package includes: a base structure including a body having a rear surface on which a dummy pad and a connection pad are arranged and a rear insulating layer disposed on the rear surface and surrounding the dummy pad and the connection pad; and a semiconductor chip disposed on the base structure and including a semiconductor layer having a front surface facing the rear surface of the body, a test pad and an input/output pad disposed on the front surface of the semiconductor layer, a first bonding pad structure disposed between the test pad and the dummy pad, a second bonding pad structure disposed between the input/output pad and the connection pad, and a bonding insulating layer disposed on the front surface of the semiconductor layer and surrounding at least a portion of each of the first bonding pad structure and the second bonding pad structure, in which the first bonding pad structure includes a first contact portion being in contact with the test pad, a first bonding pad bonded to the dummy pad, and a first seed layer extending in a first direction between the first bonding pad and the first contact portion, the second bonding pad structure includes a second contact portion being in contact with the input/output pad, a second bonding pad bonded to the connection pad, and a second seed layer extending in the first direction between the second bonding pad and the second contact portion, the first bonding pad includes first grain structures extending in a second direction, perpendicular to the first direction, and the second bonding pad includes second grain structures extending in the second direction.

According to an embodiment of the present inventive concept, a semiconductor package includes: a base structure including a body having a rear surface on which a dummy pad is disposed and a rear insulating layer disposed on the rear surface and surrounding the dummy pad; and a semiconductor chip disposed on the base structure and including a semiconductor layer having a front surface facing the rear surface of the body, a test pad disposed on the front surface of the semiconductor layer, a bonding pad structure disposed between the test pad and the dummy pad, and a bonding insulating layer surrounding at least a portion of the bonding pad structure, in which the bonding pad structure includes a contact portion being in contact with the test pad and having a lower surface positioned opposite to the test pad, a bonding pad bonded to the dummy pad, and a seed layer disposed between the bonding pad and the contact portion and extending in a first direction parallel to the lower surface of the contact portion, and the bonding insulating layer is in direct contact with a side surface of the bonding pad.

According to an embodiment of the present inventive concept, a method for manufacturing a semiconductor package includes: preparing a semiconductor chip including a test pad having a protrusion on a surface thereof, an input/output pad spaced apart from the test pad, and a first bonding insulating layer covering the test pad and the input/output pad and having a first opening exposing at least a portion of the test pad and a second opening exposing at least a portion of the input/output pad; forming a first contact portion filling the first opening and a second contact portion filling the second opening; forming a preliminary seed layer on an upper surface of the first bonding insulating layer and respective upper surfaces of the first and second contact portions; forming first and second bonding pads respectively on the first and second contact portions using the preliminary seed layer; forming a first seed layer below the first bonding pad and a second seed layer below the second bonding pad by removing portions of the preliminary seed layer; and forming a second bonding insulating layer covering side surfaces of the first and second bonding pads and side surfaces of the first and second seed layers.

### BRIEF DESCRIPTION OF DRAWINGS

The above and other aspects, and features of the present inventive concept will be more clearly understood from the following detailed description, taken in conjunction with the accompanying drawings, in which:

FIG. 1A is a perspective view illustrating a semiconductor package according to an embodiment of the present inventive concept, and FIG. 1B is a cross-sectional view taken along line I-I' of FIG. 1A;

FIG. 2 is an enlarged view illustrating region 'A' of FIG. 1A;

FIGS. 3A and 3B are enlarged views illustrating regions 'B1' and 'B2' of FIG. 2, respectively, FIG. 3C is a plan view illustrating grain structures GS of FIGS. 3A and 3B, and FIG. 3D is a graph illustrating X-ray diffraction (XRD) characteristics of the grain structures GS of FIG. 3C;

FIGS. 4A to 4G are cross-sectional views sequentially illustrating a partial manufacturing process of a method of manufacturing a semiconductor package according to an embodiment of the present inventive concept;

FIG. 5A is a perspective view illustrating a semiconductor package according to an embodiment of the present inventive concept, and FIG. 5B is a cross-sectional view taken along line II-II' of FIG. 5A;

FIG. 6A is a cross-sectional view illustrating a semiconductor package according to an embodiment of the present inventive concept, and FIG. 6B is an enlarged view illustrating region ‘C’ of FIG. 6A; and

FIG. 7 is a cross-sectional view illustrating a semiconductor package according to an embodiment of the present inventive concept.

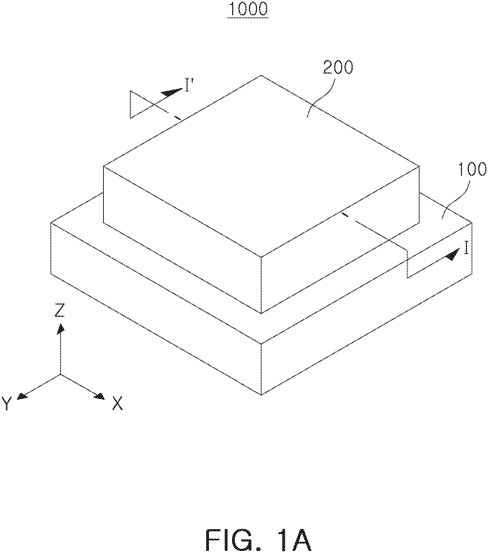

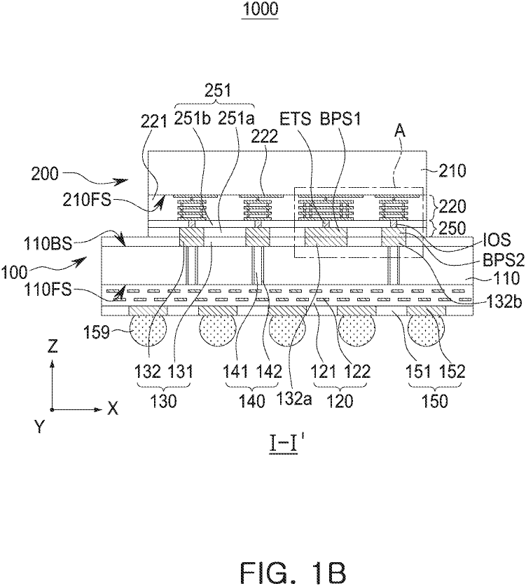

Since the drawings in FIGS. 1-7 are intended for illustrative purposes, the elements in the drawings are not necessarily drawn to scale. For example, some of the elements may be enlarged or exaggerated for clarity purpose.

### DETAILED DESCRIPTION OF THE EMBODIMENTS

Hereinafter, embodiments of the present inventive concept are described with reference to the accompanying drawings.

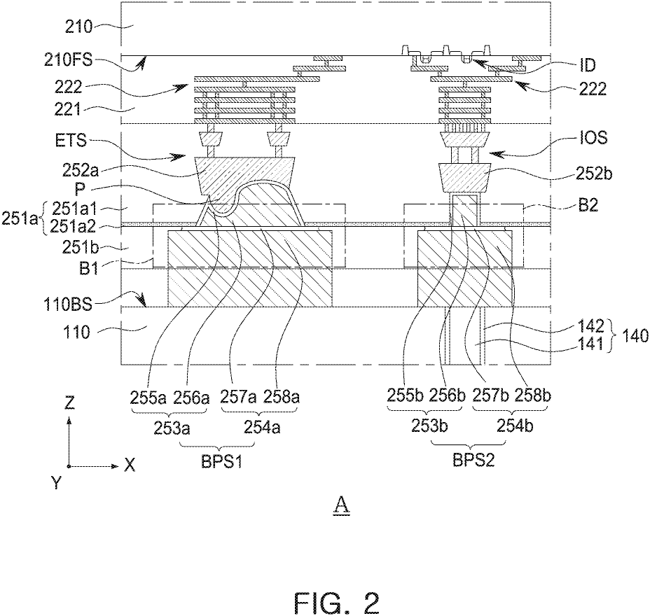

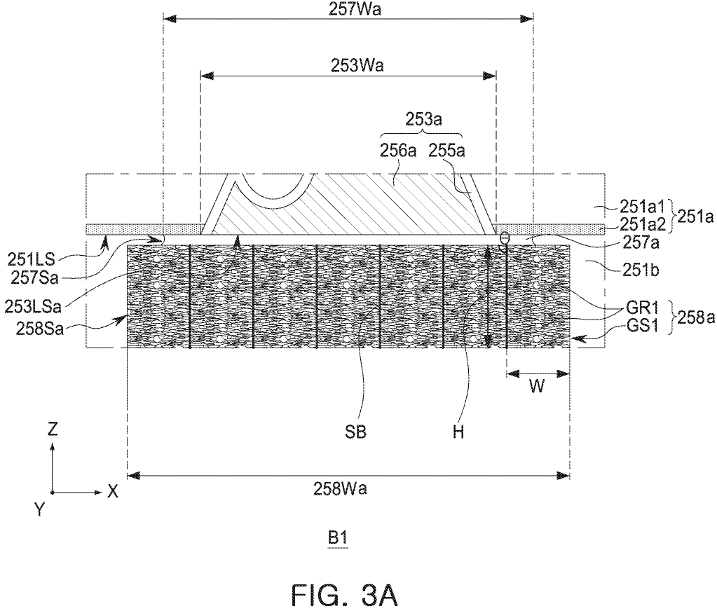

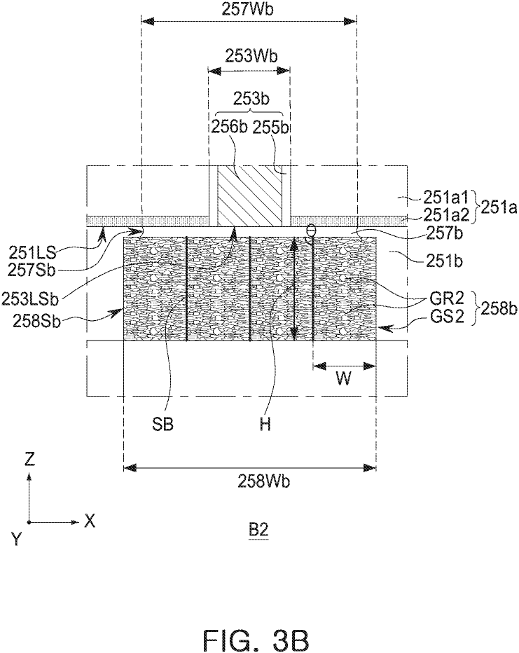

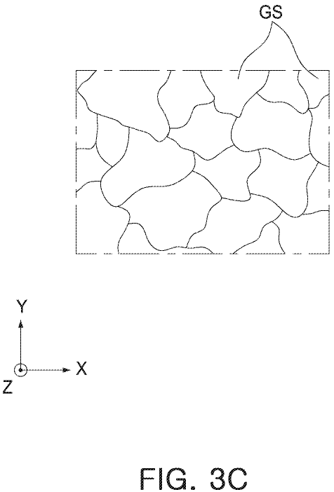

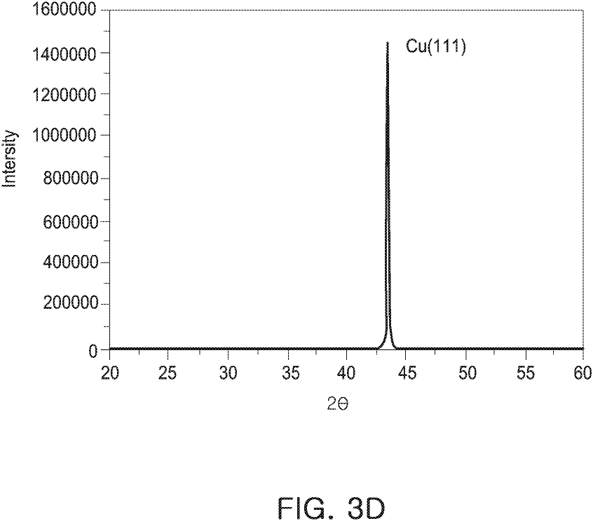

FIG. 1A is a perspective view illustrating a semiconductor package 1000 according to an embodiment of the present inventive concept, FIG. 1B is a cross-sectional view taken along line I-I' of FIG. 1A, FIG. 2 is an enlarged view illustrating region 'A' of FIG. 1A, and FIGS. 3A and 3B are enlarged views illustrating regions 'B1' and 'B2' of FIG. 2, respectively.

First, referring to FIGS. 1A and 1B, a semiconductor package 1000 according to an embodiment of the present inventive concept may include a semiconductor structure 100 and a semiconductor chip 200 stacked in a vertical direction (Z-axis direction). The semiconductor structure 100 and the semiconductor chip 200 have a structure in which elements exposed on an upper surface of the semiconductor structure 100 and a lower surface of the semiconductor chip 200 are bonded (which may be referred to as, for example, hybrid bonding, direct bonding, etc.) without a separate connection member (e.g., metal pillars, solder bumps, etc.) interposed therebetween. Hybrid bonding, which directly bonds metal interconnects together (e.g., copper (Cu) to copper (Cu) bonding) in the same operation of directly bonding the dielectrics together (e.g., oxide to oxide bonding), is better than conventional chip packaging because it provides increased chip density and shortens the lengths of the interconnect wiring between, for example, chiplets. For example, oxide to oxide bonding and Cu to Cu bonding may be formed at an interface between the semiconductor structure 100 and the semiconductor chip 200. In the present inventive concept, a first bonding pad structure BPS 1 is formed on an electrical test structure ETS of the semiconductor chip 200, and the first bonding pad structure BPS1 is directly coupled to a dummy pad 132a on an upper surface of the semiconductor structure 100, thereby stably forming a hybrid bonding structure and heat dissipation characteristics of the semiconductor package 1000 may be enhanced. For example, a larger volume of the conductive material may be provided by the above described structure to enhance heat dissipation. The ETS may be understood as an integrated conductive structure including a pad (hereinafter, referred to as a "test pad") for an electrical die sorting (EDS) test. In addition, according to the present inventive concept, since the first and second bonding pad structures BPS 1 and BPS2 include bonding pads having a 111 crystal orientation, Cu to Cu bonding is more stably formed than when structures in other crystal directions are included. In addition, when the first and second bonding pad structures BPS 1 and BPS2 include bonding pads having a 111 crystal orientation, Cu to Cu bonding may be formed at a low temperature, and thus, the reliability of the first and second bonding pad structures BPS 1 and BPS2 may be enhanced. Structural features and methods of forming the first and second bonding pad structures BPS1 and BPS2 are described below with reference to FIGS. 2 to 4F.

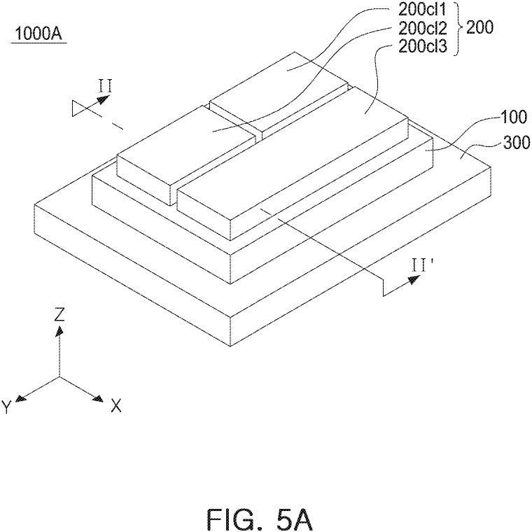

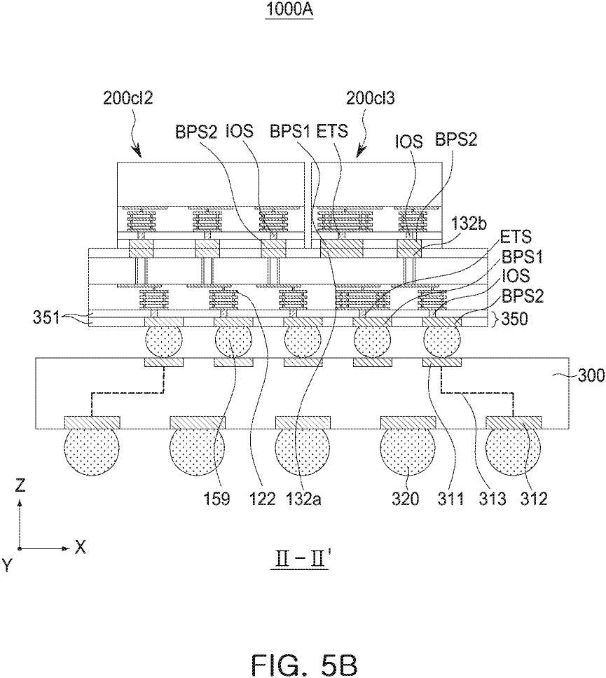

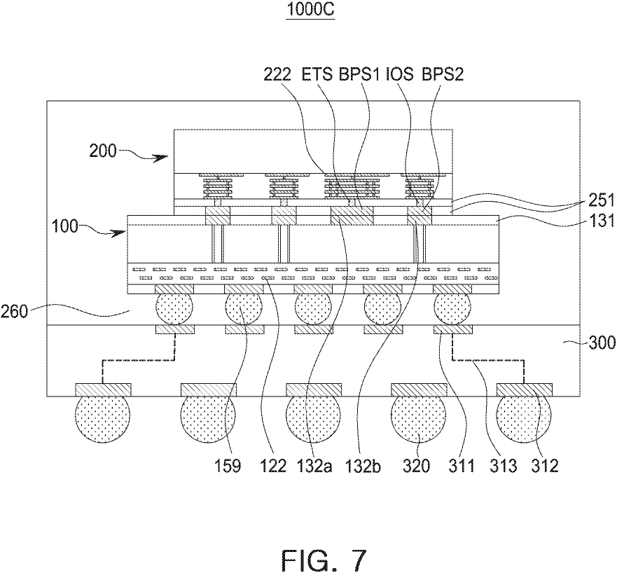

The semiconductor structure 100, which may also be referred to as a base structure, is a semiconductor wafer-based structure and may include a body 110, a circuit layer 120, a rear cover layer 130, and a through-via 140. For example, the semiconductor structure 100 may be a silicon interposer substrate, a semiconductor chip, or the like. When the semiconductor structure 100 is a semiconductor chip, the semiconductor structure 100 and the semiconductor chip 200 stacked thereon may be chiplets constituting a multi-chip module (MCM), but the present inventive concept is not limited thereto. This is described below with reference to FIG. 7. A multi-chip module (MCM), in which multiple integrated circuits (ICs), semiconductor dies or other discrete components are packaged onto a unifying substrate, is one form of system-in-package (SIP). Multiple chiplets arranged side by side on the semiconductor structure 100 and constitute a multi-chip module (MCM) will be described below with reference to FIGS. 5A and 5B.

The body 110 may be a semiconductor wafer including a semiconductor element such as, for example, silicon (Si), or germanium (Ge), or a compound semiconductor such as, for example, silicon carbide (SiC), gallium arsenide (GaAs), indium arsenide (InAs), silicon germanium (SiGe), indium antimonide (InSb), lead tellurium (PbTe) compounds, gallium phosphide (GaP), gallium antimonide (GaSb), or indium phosphide (InP).

The circuit layer 120 may be disposed on a front surface 110FS of the body 110 and may include a first interlayer insulating layer 121 and an internal interconnection 122. The first interlayer insulating layer 121 may include, for example, silicon oxide (SiO₂) or silicon nitride (Si₃N₄). In an embodiment of the present inventive concept, individual elements constituting an integrated circuit (IC) may be disposed on the front surface 110FS of the body 110. In this case, the internal interconnection 122 may be electrically connected to individual elements. Individual elements are described in detail with reference to FIG. 2. The internal interconnection 122 redistributes a rear pad 132 or the through-via 140 disposed on a rear surface 110BS positioned opposite to the front surface 110FS, and may be formed in a multilayer structure including a plurality of interconnection lines and a plurality of interconnection vias. The interconnection lines and interconnection vias may each include, for example, aluminum (Al), gold (Au), cobalt (Co), copper (Cu), nickel (Ni), lead (Pb), tantalum (Ta), tellurium (Te), titanium (Ti), tungsten (W), or a combination thereof. A barrier layer including, for example, titanium (Ti), titanium nitride (TiN), tantalum (Ta), or tantalum nitride (TaN) may be disposed between the interconnection line or/and the interconnection via and the first interlayer insulating layer 121. A front cover layer 150 may be disposed below the circuit layer 120.

The front cover layer 150 may include a front insulating layer 151 and a front pad 152. The front pad 152 may be electrically connected to the connection pad 132b among the rear pads 132 through the internal interconnection 122 and the through-via 140. However, the front pad 152 may not be electrically connected to the dummy pad 132a among the rear pads 132. The front pad 152 may provide a connection terminal through which the semiconductor structure 100 and the semiconductor chip 200 may be electrically connected to an external device. A separate connection member 159 (e.g., a solder ball, a copper pillar, etc.) may be disposed below the front pad 152, but the present inventive concept is not limited thereto. For example, the semiconductor structure 100 may hybrid-bonded to another structure (e.g., a silicon interposer) without a connection member such as a solder ball, etc. The connection member 159 may be coupled to an external device. For example, the external device may be electrically connected to the semiconductor structure 100 and the semiconductor chip 200 through the connection member 159.

The rear cover layer 130 may be disposed on the rear surface 110BS of the body 110 and may include a rear insulating layer 131 and a rear pad 132. For example, the rear insulating layer 131 may be disposed on the rear surface 110BS of the body 110, and may surround the dummy pad 132a and the connection pad 132b. The front insulating layer 151 and the rear insulating layer 131 may each include, for example, silicon oxide (SiO₂) or silicon nitride (Si₃N₄). The front pad 152 and the rear pad 132 may each include the metal material described above, similarly to the internal interconnection 122, but do not necessarily include the same type of metal material as the internal interconnection 122. The rear insulating layer 131 may include an insulating material that may be coupled to the bonding insulating layer 251 of the semiconductor chip 200, for example, silicon oxide (SiO₂). However, the present inventive concept is not limited thereto, and the rear insulating layer 131 may include, for example, silicon carbonitride (SiCN) or the like. In a similar view, the rear pad 132 may include a conductive material, that may be bonded to the bonding pad structures BPS1 and BPS2 of the semiconductor chip 200, such as, for example, copper (Cu), nickel (Ni), gold (Au), silver (Ag), or an alloy thereof. The rear pad 132 may include a dummy pad 132a coupled to the first bonding pad structure BPS1 and a connection pad 132b coupled to the second bonding pad structure BPS2. The rear surface 110BS of the body 110 may be covered by a dielectric layer (e.g., an oxide-nitride-oxide (ONO) layer). The dielectric layer may electrically insulate the rear pad 132 from a semiconductor material constituting the body 110.

The through-via 140 may pass through the body 110 to be electrically connected to the internal interconnection 122. According to an embodiment of the present inventive concept, the through-via 140 may electrically connect individual elements disposed on the front surface 110FS of the body 110 to the connection pad 132b. For example, the through-via 140 may extend from the circuit layer 120 to the bottom surface of the connection pad 132b. Meanwhile, the dummy pad 132a may be electrically insulated from the through-via 140 and the internal interconnection 122. For example, the through-via 140 may not be disposed under the dummy pad 132a to connect the dummy pad 132a to the circuit layer 120, and thus may not provide electrical connection between the dummy pad 132a and the internal interconnection 122. The through-via 140 may include a through-electrode 141 and a barrier layer 142 surrounding a side surface of the through-electrode 141. The through-electrode 141 may include, for example, tungsten (W), titanium (Ti), aluminum (Al), or copper (Cu) and may be formed by, for example, a plating process, a physical vapor deposition (PVD) process, or a chemical vapor deposition (CVD) process. For example, the through-electrode 141 may be a metal pillar. The barrier layer 142 may include a metal compound such as, for example, tungsten nitride (WN), titanium nitride (TiN), or tantalum nitride (TaN). The barrier layer 142 may be formed by, for example, a PVD process or a CVD process. A via insulating layer may be formed on a side surface of the through-via 140. The via insulating layer may electrically insulate the through-via 140 from the semiconductor material constituting the body 110. The via insulating layer may be a single layer or a multi-layer. The via insulating layer may include one or more of, for example, silicon oxide (SiO₂), silicon oxynitride (SiON), silicon nitride (Si₃N₄), a polymer, and a combination thereof.

The semiconductor chip 200 is stacked on the semiconductor structure 100 and may include a semiconductor layer 210, a circuit layer 220, and a bonding layer 250. In the drawing, one semiconductor chip 200 is illustrated, but the present inventive concept is not limited thereto. For example, in an embodiment of the present inventive concept, two or more semiconductor chips may be stacked on the semiconductor structure 100 in a vertical direction (Z-axis direction) or arranged in a horizontal direction (X-axis or Y-axis directions). Since the semiconductor layer 210 and the circuit layer 220 have characteristics similar to those of the body 110 and the circuit layer 120 of the semiconductor structure 100, redundant descriptions thereof are omitted, and then details thereof are described below with reference to FIG. 2.

The bonding layer 250 may include a bonding insulating layer 251, an electrical test structure ETS, an input/output structure IOS, and first and second bonding pad structures BPS1 and BPS2. The bonding insulating layer 251 may include an insulating material, that may be coupled to the rear insulating layer 131 of the semiconductor structure 100, such as, for example, silicon oxide (SiO₂), silicon nitride (Si₃N₄), or the like. The electrical test structure ETS and the input/output structure IOS may be electrically connected to the internal circuit 222 of the circuit layer 220 and may include a conductive material. For example, the electrical test structure ETS and the input/output structure IOS may include, for example, aluminum (Al) or an aluminum (Al) alloy. The first and second bonding pad structures BPS1 and BPS2 may include a material the same as that of the rear pad 132 so that the first and second bonding pad structures BPS1 and BPS2 may be coupled to the rear pad 132 of the semiconductor structure 100. For example, the first and second bonding pad structures BPS1 and BPS2 may be formed of, for example, copper (Cu), nickel (Ni), gold (Au), silver (Ag), or an alloy thereof.

The present inventive concept introduces the first bonding pad structure BPS 1 having a specific structure on the electrical test structure ETS in which a surface is damaged in the EDS test, thereby contributing to stable hybrid bonding between the semiconductor structure 100 and the semiconductor chip 200, and increases density of a metal material, thereby enhancing heat dissipation characteristics. For example, during the EDS test, a surface of the EDS test pad (i.e., test pad 252a) may be deformed (e.g., pile-up). The first bonding pad structure BPS1 is formed on the deformed surface to provide a flat surface. For example, the EDS test pad (i.e., test pad 252a) may also be used as a thermal pad. In addition, since the second bonding pad structure BPS2 on the input/output structure IOS also has characteristics similar to those of the first bonding pad structure BPS1, the second bonding pad structure BPS2 may contribute to stable hybrid bonding and enhancement of heat dissipation characteristics. Hereinafter, the first and second bonding pad structures BPS1 and BPS2 are described in detail with reference to FIG. 2 together with FIG. 1B. FIG. 2 is a partially enlarged view illustrating the first and second bonding pad structures BPS1 and BPS2 of FIG. 1B.

Referring to FIG. 2 together with FIG. 1B, the first bonding pad structures BPS1 and the second bonding pad structures BPS2 may be electrically and physically connected to the electrical test structure ETS and the input/output structure IOS, respectively. As will be described below, the first and second bonding pad structures BPS1 and BPS2 have structurally similar characteristics, which is due to the fact that the first and second bonding pad structures BPS1 and BPS2 are formed in the same process. For example, a lower surface 253LSa (see FIG. 3A) of a first contact portion 253a and a lower surface 253LSb (see FIG. 3B) of a second contact portion 253b are coplanar and may provide a flat surface on which first and second seed layers 257a and 257b are formed together with a lower surface 251LS of a first bonding insulating layer 251a. For example, the first and second seed layers 257a and 257b may also be formed on portions of the lower surface 251LS of the first bonding insulating layer 251a. Meanwhile, first and second bonding pads 258a and 258b may have different sizes corresponding to the sizes of a test pad 252a and an input/output pad 252b, respectively. For example, the first bonding pad 258a may have a width 258Wa greater than a width 258 Wb of the second bonding pad 258b. This is described with reference to FIGS. 3A and 3B.

The first bonding pad structure BPS1 is disposed between the test pad 252a and the dummy pad 132a and may include a first contact portion 253a and a first pad portion 254a.

The first contact portion 253a may contact the test pad 252a inside the first bonding insulating layer 251a and may have a lower surface 253LSa positioned opposite to the test pad 252a. The first contact portion 253a may include a first contact seed layer 255a and a first contact via 256a. The first contact seed layer 255a may be formed between the first contact via 256a and the first bonding insulating layer 251a and may be connected along a protrusion P of a surface of the test pad 252a. The protrusion P is caused by EDS test. The first contact seed layer 255a may be used as a seed layer in a plating process for forming the first contact via 256a, and a metal material forming the first contact via 256a may be used as a diffusion barrier layer to prevent the metal material forming the first contact via 256a from being diffused into the first bonding insulating layer 251a. The first contact seed layer 255a may be formed of, for example, a metal material such as titanium (Ti) or copper (Cu). The first contact via 256a may be formed of, for example, a metal material such as copper (Cu) or an alloy including the same. The first contact seed layer 255a and the first contact via 256a may provide a lower surface 253LSa of the first contact portion 253a in contact with the first pad portion 254a. The test pad 252a may have a protrusion P having a pile-up surface, while the first contact portion 253a may have the lower surface 253LSa having a flat surface for forming the first pad portion 254a. The test pad 252a having a protrusion P with a pile-up surface may not be suitable for hybrid bonding, and thus, the first contact portion 253a is provided with a flat surface so that the first pad portion 254a formed on the first contact portion 253a may have a lower surface being flat, thereby being suitable for hybrid bonding.

The first pad portion 254a may include the first bonding pad 258a bonded to the dummy pad 132a and the first seed layer 257a disposed between the first bonding pad 258a and the first contact portion 253a and extending in a first direction (X-axis direction) parallel to the lower surface 253LSa of the first contact portion 253a. The first seed layer 257a may be spaced apart from a side surface of the first bonding pad 258a. For example, a side surface of the first seed layer 257a may be spaced apart from a corresponding one of the side surfaces of the first bonding pad 258a. The first seed layer 257a may be used as a seed layer and a diffusion barrier layer in a plating process of forming the first bonding pad 258a. The first seed layer 257a may be formed of, for example, a metal material such as titanium (Ti) or copper (Cu). In an embodiment of the present inventive concept, the first seed layer 257a may include titanium (Ti) or a titanium (Ti) alloy. The first bonding pad 258a may be formed of, for example, a metal material such as copper (Cu) or an alloy including the same. According to the present inventive concept, a crystal direction of the first bonding pad 258a may be uniformly controlled by growing the first bonding pad 258a in a second direction (Z-axis direction) perpendicular to the first seed layer 257a. As a result, a bond between the first bonding pad 258a and the dummy pad 132a may be stably formed. The first pad portion 254a may be formed using, for example, a semi-additive process (SAP). For example, the first bonding pad 258a may be formed of copper (Cu) using the SAP, and in this case, the Cu pad may grow in a 111 crystal orientation. Since copper (Cu) may have high diffusivity on the 111 plane, Cu to Cu bonding may be formed at a low temperature. Thus, the first bonding pad 258a may be directly coupled to the dummy pad 132a on an upper surface of the semiconductor structure 100, thereby stably forming a hybrid bonding structure, and heat dissipation characteristics of the semiconductor package 1000 may be enhanced. For example, the first seed layer 257a may have a width equal to or smaller than a width of the first bonding pad 258a. This is described with reference to FIG. 3A.

The second bonding pad structure BPS2 may be disposed between the input/output pad 252b and the connection pad 132b and may include a second contact portion 253b and a second pad portion 254b.

The second contact portion 253b may contact the input/output pad 252b inside the first bonding insulating layer 251a and may have a lower surface 253LSb positioned opposite to the input/output pad 252b. The second contact portion 253b may include a second contact seed layer 255b and a second contact via 256b. The second contact seed layer 255b may be formed between the second contact via 256b and the first bonding insulating layer 251a and may be connected along a surface of the input/output pad 252b. The second seed layer 257b may be spaced apart from a side surface of the second bonding pad 258b. For example, a side surface of the second seed layer 257b may be spaced apart from a corresponding one of the side surfaces of the second bonding pad 258b. The second contact seed layer 255b may be used as a seed layer and a diffusion barrier layer in a plating process for forming the second contact via 256b. The second contact seed layer 255b may be formed of, for example, a metal material such as titanium (Ti) or copper (Cu). The second contact via 256b may be formed of, for example, a metal material such as copper (Cu) or an alloy including the same. The second contact seed layer 255b and the second contact via 256b may provide a lower surface 253LSb of the second contact portion 253b in contact with the second pad portion 254b.

The second pad portion 254b may include a second bonding pad 258b bonded to the connection pad 132b and a second seed layer 257b disposed between the second bonding pad 258b and the second contact portion 253b and extending in the first direction (X-axis direction) parallel to the lower surface 253LSb of the second contact portion 253b. The second seed layer 257b may be used as a seed layer and a diffusion barrier layer in a plating process of forming the second bonding pad 258b. The second seed layer 257b may be formed of, for example, a metal material such as titanium (Ti) or copper (Cu). In an embodiment of the present inventive concept, the second seed layer 257b may include titanium (Ti) or a titanium (Ti) alloy. The second bonding pad 258b may be formed of, for example, a metal material such as copper (Cu) or an alloy including the same. According to the present inventive concept, a crystal direction of the second bonding pad 258b may be uniformly controlled by growing the second bonding pad 258b in the second direction (Z-axis direction) perpendicular to the second seed layer 257b, and as a result, the coupling between the second bonding pad 258b and the connection pad 132b may be stably formed. The second pad portion 254b may be formed using, for example, a semi-additive process (SAP). For example, the second bonding pad 258b may be formed of copper (Cu) using the SAP, and in this case, the Cu pad may grow in a 111 crystal orientation. Since copper (Cu) may have high diffusivity on the 111 plane, Cu to Cu bonding may be formed at a low temperature. Thus, the second bonding pad 258b may be directly coupled to the connection pad 132b on an upper surface of the semiconductor structure 100, thereby stably forming a hybrid bonding structure. For example, the second seed layer 257b may have a width equal to or smaller than a width of the second bonding pad 258b. This is described with reference to FIG. 3B.

The semiconductor layer 210 may have a front surface 210FS facing the rear surface 110BS of the body 110. The electrical test structure ETS and the input/output structure IOS may include the test pad 252a and the input/output pad 252b disposed on the front surface 210FS of the semiconductor layer 210, respectively. According to an embodiment of the present inventive concept, the electrical test structure ETS and the input/output structure IOS may further include a connection structure connecting the test pad 252a and the input/output pad 252b to the internal circuit 222 of the circuit layer 220, respectively. The test pad 252a may have a protrusion P in which a surface is piled up by contact with a probe in the EDS test. For example, during the EDS test, the test probe may make physical contact with the test pad 252a, and the surface of the test pad 252a may be deformed by the physical contact to leave a protrusion with a pile-up surface. The test pad 252a and the input/output pad 252b may include a conductive material different from that of the first and second bonding pads 258a and 258b. For example, the first and second bonding pads 258a and 258b may be formed of a first material such as, for example, copper (Cu), nickel (Ni), gold (Au), silver (Ag), or a combination thereof, and the test pad 252a and the input/output pad 252b may include a second material such as, for example, aluminum (Al) or an aluminum (Al) alloy.

The bonding layer 250 may include the electrical test structure ETS and the input/output structure IOS, the first bonding insulating layer 251a surrounding portions of the first and second bonding pad structures BPS1 and BPS2, e.g., the first contact portion 253a and the second contact portion 253b, and a second bonding insulating layer 251b, on which the first bonding insulating layer 251a is disposed, surrounding the other portions of the first and second bonding pad structures BPS1 and BPS2, e.g., the first pad portion 254a and the second pad portion 254b. Also, the first bonding insulating layer 251a may surround the test pad 252a and the input/output pad 252b. The first and second bonding insulating layers 251a and 251b may include, for example, silicon oxide (SiO₂), silicon nitride (Si₃N₄), or the like. The first bonding insulating layer 251a may include a dielectric layer 251a1 and a barrier layer 251a2. The barrier layer 251a2 may be disposed between the dielectric layer 251a1 and the second bonding insulating layer 251b and function as an etch stop layer during an etching process for forming the first and second bonding pad structures BPS1 and BPS2. The barrier layer 251a2 may include, for example, silicon nitride (Si₃N₄) or aluminum oxide (A1₂O3). The second bonding insulating layer 251b may include an insulating material that may be coupled to the rear insulating layer 131, for example, silicon oxide (SiO₂).

The circuit layer 220 may be disposed between the semiconductor layer 210 and the bonding layer 250 and may include a second interlayer insulating layer 221 and an internal circuit 222 electrically connected to the individual devices IDs. In an embodiment of the present inventive concept, the circuit layer 220 may be disposed between the front surface 210FS of the semiconductor layer 210 and the first bonding insulating layer 251a and may include individual elements (e.g., individual devices IDs) electrically connected to the input/output pad 252b, while the test pad 252a is electrically insulated from the individual elements (e.g., individual devices IDs). The individual devices IDs may include field-effect transistors (FETs) such as, for example, planar FETs and FinFETs, flash memory, memory devices such as, for example, Dynamic Random Access Memory (DRAM), static RAM (SRAM), electrically erasable programmable read-only memory (EEPROM), phase-change RAM (PRAM), magnetic RAM (MRAM), ferroelectric RAM (FeRAM), and resistive RAM (RRAM), logic devices such as, for example, AND, OR, and NOT, and various active and/or passive components such as, for example, system large-scale integration (LSI), complementary metal-oxide-semiconductor image sensor (CIS), and microelectromechanical systems (MEMS). The individual devices IDs may include, for example, a gate structure disposed between conductive regions of the semiconductor layer 210. The semiconductor layer 210 may include a conductive region adjacent to the gate structure and isolation regions on one side of the conductive region. The conductive region may be, for example, a well doped with an impurity or a structure doped with an impurity. The isolation region may include various device isolation structures such as a shallow trench isolation (STI) structure. The semiconductor layer 210 may have characteristics similar to those of the body 110 of the semiconductor structure 100. For example, similar to the body 110, the semiconductor layer 210 may also include a semiconductor element and/or a compound semiconductor. The internal circuit 222 may connect the electrical test structure ETS or the test pad 252a to an electrical test circuit, may connect the input/output structure IOS or the input/output pad 252b to the individual devices IDs and the conductive region of the semiconductor layer 210, or may interconnect the individual devices IDs to each other. The circuit layer 220 may have characteristics similar to those of the circuit layer 120 of the semiconductor structure 100. The electrical test structure ETS or the test pad 252a may be electrically insulated from the individual devices ID. Also, the electrical test structure ETS or the test pad 252a may be electrically insulated from the through-via 140, the internal interconnection 122, and the individual elements disposed on the front surface 110FS of the body 110.

As described above, in the present inventive concept, by introducing the first bonding pad 258a bonded to the dummy pad 132a on the test pad 252a, a hybrid bonding structure may be formed and the heat dissipation characteristics of the semiconductor package 1000 may be enhanced. Also, since the first and second bonding pads 258a and 258b are formed of crystal grains having a specific crystal direction, the first and second bonding pads 258a and 258b may be stably coupled to the dummy pad 132a and the connection pad 132b, respectively. Hereinafter, crystal directions of the first and second bonding pads 258a and 258b are described with reference to FIGS. 3A to 3D. FIGS. 3A and 3B schematically illustrate the crystal structures of the first bonding pad 258a and the second bonding pad 258b, respectively. FIG. 3C is a plan view illustrating grain structures GS constituting the first bonding pad 258a and the second bonding pad 258b, and FIG. 3D is a graph illustrating X-ray diffraction (XRD) characteristics of the grain structures GS of FIG. 3C.

Referring to FIGS. 3A and 3B, the first bonding pad 258a includes first grain structures GS1 having first grains GR1 and extending in a second direction (Z-axis direction), and the second bonding pad 258b may include second grain structures GS2 having second grains GR2 and extending in the second direction (Z-axis direction). The first and second grain structures GS 1 and GS2 may have a column shape extending vertically with respect to lower surfaces of the first and second seed layers 257a and 257b, respectively. Here, the extending direction of the first and second grain structures GS1 and GS2 may be understood as a meaning that the first and second grain structures GS1 and GS2 are grown in a direction away from lower surfaces of the first and second seed layers 257a and 257b during a plating process. Accordingly, each boundary SB between the first grain structures GS 1 and between the second grain structures GS2 may have an angle θ ranging from about 45 degrees to about 90 degrees, ranging from about 60 degrees to about 90 degrees, or ranging from about 80 degrees to about 90 degrees with respect to lower surfaces of the first and second seed layers 257a and 257b. As a result, as illustrated in FIGS. 3C and 3D, the grain structures GS constituting the first bonding pad 258a and the second bonding pad 258b may have a 111 crystal orientation. The term "about" as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, "about" may mean within one or more standard deviations, or within ± 30%, 20%, 10%, 5% of the stated value.

Referring to FIG. 3D, it can be seen that the grain structures GS are grown to have a 111 crystal orientation according to a result of the X-ray diffraction analysis. Copper (Cu) may have high diffusivity on the 111 plane. This may enhance reliability of the first and second bonding pads 258a and 258b and allow Cu to Cu bonding to be stably formed between the first and second bonding pads 258a and 258b and the rear pad 132 at a low temperature (e.g., 300° C. or lower). For example, the low temperature may be in a range from about 100° C. to about 300° C., but the present inventive concept is not limited thereto. In addition, at least some of the first and second crystal grains GR1 and GR2 may include a nanotwin structure. For example, at least a portion of the first and second grain structures GS1 and GS2 may include a nanotwin structure. Nanotwin means that a distance between the twin planes in which the grains are symmetrical is so small in nano-scale and the mechanical properties of the material may be enhanced.

In addition, by a process (e.g., an etching process) of forming the first and second grain structures GS 1 and GS2, a side surface 257Sa of the first seed layer 257a and a side surface 257Sb of the second seed layer 257b may be concavely rounded and may have a step with a side surface 258Sa of the first bonding pad and a side surface 258Sb of the second bonding pad 258b, respectively. For example, the first seed layer 257a may overlap the first bonding pad 258a in the second direction (Z-axis direction), and a width 257Wa of the first seed layer 257a may be greater than a width 253Wa of the first contact portion 253a and smaller than a width 258Wa of the first bonding pad 258a. The widths 257Wa, 258Wa and 253Wa are measured in the first direction (X-axis direction). Since the width 253Wa is measured at the lower surface 253LSa of the first contact portion 253a, the width 257Wa of the first seed layer 257a may be greater than the width 253Wa of the lower surface 253LSa of the first contact portion 253a and smaller than a width 258Wa of the first bonding pad 258a in the first direction (X-axis direction). Also, the second seed layer 257b may overlap the second bonding pad 258b in the second direction (Z-axis direction) perpendicular to the first direction (X-axis direction), and a width 257 Wb of the second seed layer 257b may be greater than a width 253 Wb of the second contact portion 253b and smaller than a width 258 Wb of the second bonding pad 258b. Accordingly, at least a portion of each of the first and second bonding pads 258a and 258b may not overlap the first and second seed layers 257a and 257b in the second direction (Z-axis direction). In a similar view, the second bonding insulating layer 251b may be in direct contact with respective side surfaces 257Sa, 257Sb, 258Sa, and 258Sb of the first and second seed layers 257a and 257b and the first and second bonding pads 258a and 258b. Meanwhile, the first bonding pad 258a may have a width 258Wa greater than the width 258 Wb of the second bonding pad 258b in the first direction (X-axis direction). For example, the width 258Wa of the first bonding pad 258a may be about 30 µm or greater, for example, may range from about 30 µm to about 70 µm, or may range from about 40 µm to about 60 µm, and the width 258 Wb of the second bonding pad 258b may be about 20 µm or smaller, for example, may range from about 0.1 µm to about 20 µm, or may range from about 0.2 µm to about 10 µm.

The sizes of the first and second grain structures GS1 and GS2 are not particularly limited. For example, the first and second grain structures GS 1 and GS2 may have a width W of about 1 µm or smaller, for example, ranging from about 1 µm to about 0.0001 µm, ranging from about 1 µm to about 0.001 µm, or ranging from about 1 µm to about 0.01 µm in the first direction (X-axis direction). However, the width W of the first and second grain structures GS 1 and GS2 is not limited to the numerical ranges mentioned above and may vary depending on the conditions of the plating process. In addition, the first and second grain structures GS1 and GS2 may have a height H of about 0.5 µm or greater, for example, ranging from about 0.5 µm to about 50 µm, ranging from about 0.5 µm to about 40 µm, or ranging from about 0.5 µm to about 30 µm in the second direction (Z-axis direction). The height H of the first and second grain structures GS 1 and GS2 is also not limited to the numerical ranges mentioned above.

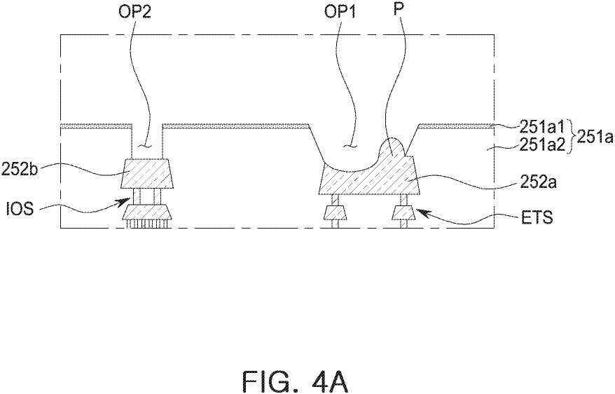

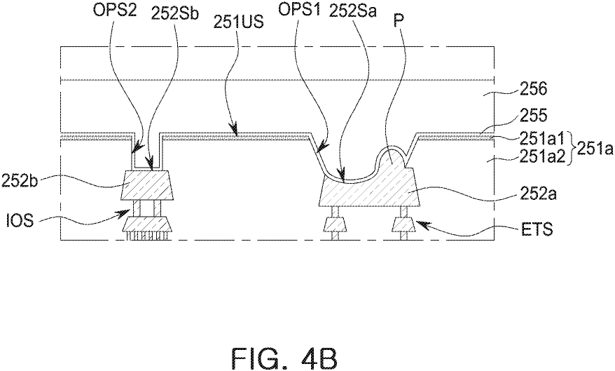

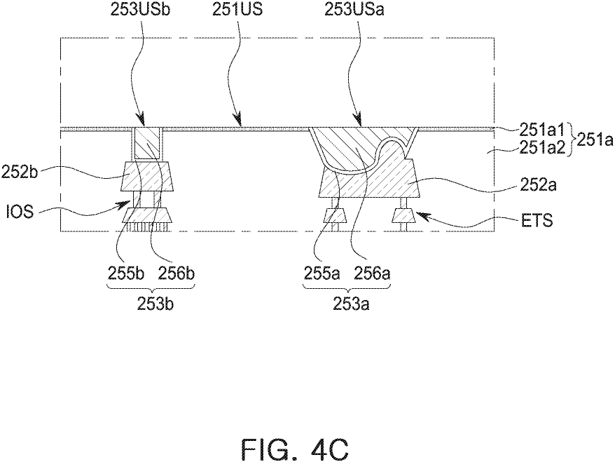

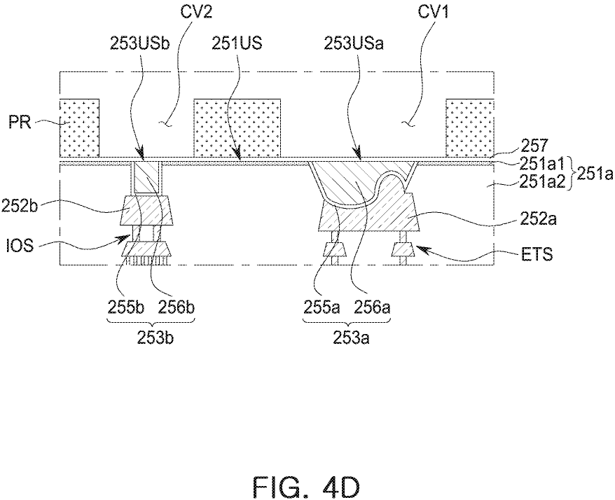

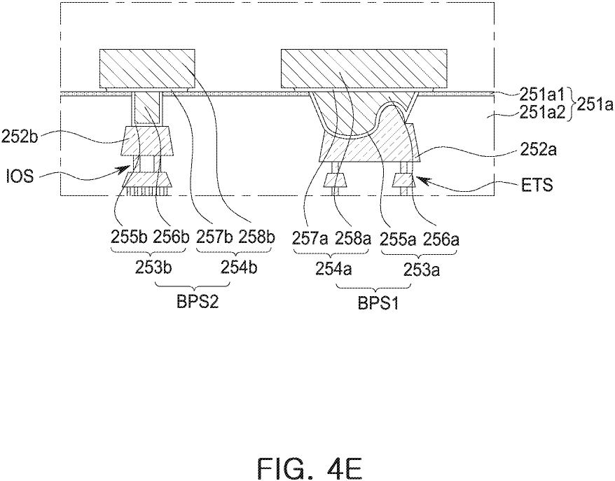

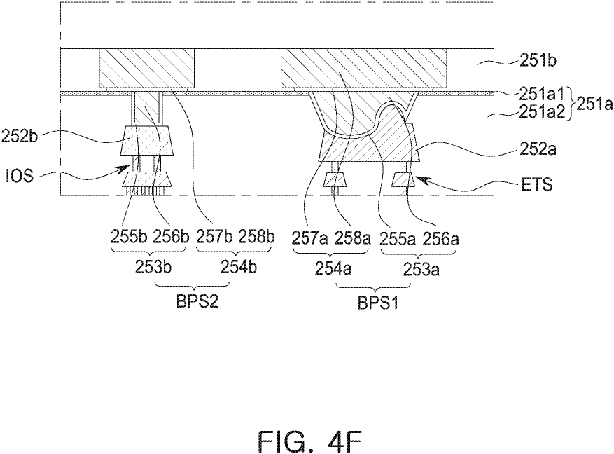

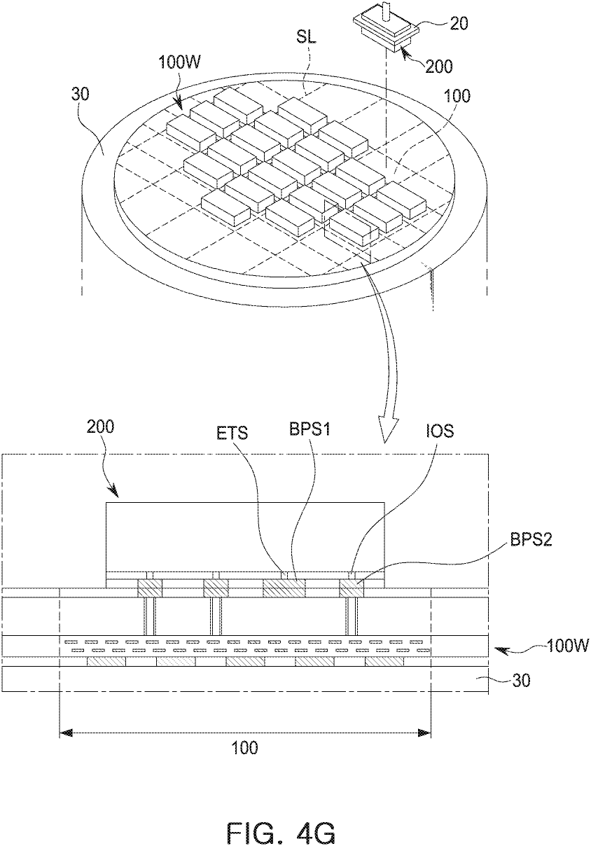

FIGS. 4A to 4G are cross-sectional views sequentially illustrating a partial manufacturing process of a method of manufacturing the semiconductor package 1000 according to an embodiment of the present inventive concept. FIGS. 4A to 4F illustrate a manufacturing process of the first and second bonding pad structures BPS 1 and BPS2 described above with reference to FIGS. 1A to 3D, and FIG. 4G illustrates a process of bonding the semiconductor structure 100 and the semiconductor chip 200. In FIGS. 4A to 4F, a vertical direction is reversed compared to FIGS. 1A to 3D, so the expressions 'top' and 'bottom' are based on FIGS. 4A to 4F.

Referring to FIG. 4A, a semiconductor chip 200 including a test pad 252a having a protrusion P on a surface thereof, an input/output pad 252b spaced apart from the test pad 252a, a first bonding insulating layer 251a covering the test pad 252a and the input/output pad 252b and having a first opening OP1 exposing at least a portion of the test pad 252a and a second opening OP2 exposing at least a portion of the input/output pad 252b is prepared. The first opening OP1 and the second opening OP2 may be formed by etching portions of the first bonding insulating layer 251a. The first opening OP1 may be formed to be greater than the second opening OP2 in consideration of a size of the test pad 252a.

Referring to FIG. 4B, a preliminary contact seed layer 255 may be conformally formed on an upper surface 251US of the first bonding insulating layer 251a, respective inner wall surfaces OPS1 and OPS2 of the first and second openings OP1 and OP2, a surface 252Sa of the test pad 252a exposed through the first opening OP1, and a surface 252Sb of the input/output pad 252b exposed through the second opening OP2. The preliminary contact seed layer 255 may be formed by depositing a metal material, for example, titanium (Ti), copper (Cu), or the like. The preliminary contact seed layer 255 may be formed using a process such as, for example, electroless plating, chemical vapor deposition (CVD), or physical vapor deposition (PVD). Thereafter, a preliminary contact via layer 256 filling the first and second openings OP1 and OP2 may be formed on the preliminary contact seed layer 255. The preliminary contact via layer 256 may be formed by performing a plating process using the preliminary contact seed layer 255. The preliminary contact via layer 256 may be formed of a metal material, for example, copper (Cu) or an alloy including the same. Thereafter, portions of the preliminary contact seed layer 255 and the preliminary contact via layer 256 may be removed to form the first contact portion 253a and the second contact portion 253b of FIG. 4C. The preliminary contact seed layer 255 and the preliminary contact via layer 256 may be removed using a planarization process (e.g., a chemical mechanical polishing (CMP) process).

Referring to FIG. 4C, a first contact portion 253a filling the first opening OP1 and a second contact portion 253b filling the second opening OP2 may be formed. The first contact portion 253a may include a first contact seed layer 255a and a first contact via 256a on the first contact seed layer 255a, and the second contact portion 253b may include a second contact seed layer 255b and a second contact via 256b on the second contact seed layer 255b. By the planarization process (e.g., a CMP process) described above, the upper surface 251US of the first bonding insulating layer 251a, the upper surface 253USa of the first contact portion 253a, and the upper surface 253USb of the second contact portion 253b may be substantially coplanar with each other, and may provide a flat surface.

Referring to FIG. 4D, a preliminary seed layer 257 may be formed on the upper surface 251US of the first bonding insulating layer 251a, the upper surface 253USa of the first contact portion 253a, and the upper surface 253USb of the second contact portion 253b. For example, the upper surface 251US of the first bonding insulating layer 251a, the upper surface 253USa of the first contact portion 253a, and the upper surface 253USb of the second contact portion 253b may provide a flat surface on which the preliminary seed layer 257 is formed, and thus, the preliminary seed layer 257 may have a flat surface for electroplating. The preliminary seed layer 257 may be formed by depositing a metal material, for example, titanium (Ti), copper (Cu), or the like. The preliminary seed layer 257 may be formed using a process such as electroless plating process, CVD process, or PVD process. Thereafter, a photosensitive material layer PR may be formed on the preliminary seed layer 257. Subsequently, the photosensitive material layer PR may be patterned to form a first cavity CV1 on the first contact portion 253a and a second cavity CV2 on the second contact portion 253b. The photosensitive material layer PR may be patterned using a photolithography process. Next, the first bonding pad 258a and the second bonding pad 258b of FIG. 4E may be respectively formed in the first cavity CV1 and the second cavity CV2 by performing an electroplating process using the preliminary seed layer 257. Next, the photosensitive material layer PR may be removed and a portion of the preliminary seed layer 257 may be removed to form the first seed layer 257a and the second seed layer 257b of FIG. 4E. The process of removing a portion of the preliminary seed layer 257 may include a wet etching process, but the present inventive concept is not limited thereto.

Referring to FIG. 4E, the first bonding pad structure BPS1 and the second bonding pad structure BPS2 may be completed through the processes of FIGS. 4A to 4D. In the process of etching the preliminary seed layer 257 of FIG. 4D, the first seed layer 257a and the second seed layer 257b may be formed to have a width smaller than the width of the first bonding pad 258a and the second bonding pad 258b, respectively. Also, as described above with reference to FIGS. 3A to 3D, the first bonding pad 258a and the second bonding pad 258b may include grain structures having a 111 crystal orientation. For example, the grain structures of copper (Cu) may be grown in a direction away from the upper surface of the preliminary seed layer 257 during the electroplating process. As a result, the grain structures included in the first bonding pad 258a and the second bonding pad 258b may have a 111 crystal orientation.

Referring to FIG. 4F, a second bonding insulating layer 251b covering side surfaces of the first bonding pad 258a and the second bonding pad 258b and side surfaces of the first seed layer 257a and the second seed layer 257b may be formed. The second bonding insulating layer 251b may be formed by, for example, depositing silicon oxide (SiO₂), silicon carbonitride (SiCN), or the like. The second bonding insulating layer 251b, the first bonding pad 258a, and the second bonding pad 258b formed through the process described above may form a hybrid bonding structure as shown in FIG. 4G.

Referring to FIG. 4G, the semiconductor chip 200 may be pre-bonded on a wafer 100W disposed on an electrostatic chuck 30 using a pick-and-place device 20. The wafer 100W may include semiconductor structures 100 divided by scribe lanes SL. The semiconductor chip 200 may include a first bonding pad structure BPS1 and a second bonding pad structure BPS2 and may be directly disposed on the semiconductor structures 100. Here, "pre-bonding" may be understood as placing the semiconductor chip 200 on the corresponding semiconductor structure 100 without applying pressure or heat. Thereafter, oxide to oxide bonding and Cu to Cu bonding may be performed to bond the semiconductor chip 200 to the semiconductor structure 100. For example, to bond the semiconductor chip 200 to the semiconductor structure 100, a heat treatment with a low temperature (e.g., 300° C. or lower) may be applied to bond the first bonding pad 258a of the semiconductor chip 200 to the dummy pad 132a of the semiconductor structure 100, to bond the second bonding pad 258b of the semiconductor chip 200 to the connection pad 132b the semiconductor structure 100, and to bond the second bonding insulating layer 251b of the semiconductor chip 200 to the rear insulating layer 131 the semiconductor structure 100.

FIG. 5A is a perspective view illustrating a semiconductor package 1000A according to an embodiment of the present inventive concept, and FIG. 5B is a cross-sectional view taken along line II-II' of FIG. 5A.

Referring to FIGS. 5A and 5B, the semiconductor package 1000A according to an embodiment of the present inventive concept may have characteristics the same as or similar to those described above with reference to FIGS. 1A to 4G, except that the semiconductor chip 200 is provided as chiplets 200c11, 200c12, and 200cl3 arranged side by side on the semiconductor structure 100. According to an embodiment of the present inventive concept, the semiconductor structure 100 and the semiconductor chip 200 may be mounted on a package substrate 300.

The chiplets 200c11, 200c12, and 200cl3 may refer to each chip constituting a multi-chip module (MCM). The MCM may include, for example, an input/output (I/O) chip, a central processing unit (CPU), a graphics processing unit (GPU), a field programmable gate array (FPGA) chip, etc. For example, in FIG. 5A, the first chiplet 200c11 may be a GPU chip, the second chiplet 200c12 may be a CPU chip, and the third chiplet 200cl3 may be an FPGA chip. The number of chiplets stacked on the semiconductor structure 100 is not particularly limited, and for example, two or less or four or more chiplets may be mounted on the semiconductor structure 100. Here, the chiplet or chiplet technology may refer to a semiconductor chip manufactured to be differentiated according to a size and function of a device or technology of manufacturing such a semiconductor chip.

The semiconductor structure 100 may be, for example, an active interposer performing a function of an I/O chip. The semiconductor structure 100 may include one or more, for example, an I/O device, a DC/DC converter, a sensor, a test circuit, and the like therein. Accordingly, the chiplets 200c11, 200c12, and 200cl3 and the semiconductor structure 100 may constitute the MCM.

In an embodiment of the present inventive concept, a base bonding layer 350 may be formed below the semiconductor structure 100. The base bonding layer 350 may be formed through the processes of FIGS. 4A to 4F. The base bonding layer 350 may include an electrical test structure ETS, an input/output structure IOS, a first bonding pad structure BPS1, a second bonding pad structure BPS2, and a base bonding insulating layer 351 surrounding these elements. Since the components of the base bonding layer 350 have characteristics similar to those of the components of the bonding layer 250 of the semiconductor chip 200 described above with reference to FIGS. 1A to 3D, redundant descriptions thereof are omitted. In the drawing, the semiconductor structure 100 is mounted on the package substrate 300 through a connection member 159, but the present inventive concept is not limited thereto. For example, the base bonding layer 350 may form hybrid bonding with the package substrate 300 according to types of the base substrate (e.g., a silicon substrate).

The package substrate 300 may include a lower pad 312 disposed on a lower surface of a body, an upper pad 311 disposed on an upper surface of the body, and a redistribution circuit 313 electrically connecting the lower pad 312 to the upper pad 311. In an embodiment of the present inventive concept, the upper pad 311 may be connected to the second bonding pad structure BPS2 or the first bonding pad structure BPS 1 positioned in the base bonding layer 350 through the connection member 159. The package substrate 300 may be a substrate for a semiconductor package including, for example, a printed circuit board (PCB), a ceramic substrate, a glass substrate, a tape wiring board, or the like. The body of the package substrate 300 may include different materials depending on the type of the substrate. For example, when the package substrate 300 is a PCB, the package substrate 300 may be in a form in which an interconnection layer is additionally stacked on one side or both sides of a body copper clad laminate or a copper clad laminate. A solder resist layer may be formed on each of a lower surface and an upper surface of the package substrate 300. The upper and lower pads 311 and 312 and the redistribution circuit 313 may form an electrical path connecting the lower surface and the upper surface of the package substrate 300. For example, the package substrate 300 may function as a redistribution substrate. Various functions of the chiplets 200c11, 200c12, and 200cl3 through various second bonding pad structures BPS2 positioned in the base bonding layer 350 may be redistributed by the package substrate 300. An external connection terminal 320 connected to the lower pad 312 may be disposed below the package substrate 300. The external connection terminal 320 may be formed of a conductive material having a shape such as a ball or a pin. For example, the external connection terminal 320 may be a solder ball, and may include a solder material, such as one or more of, for example, tin (Sn), silver (Ag), zinc (Zn), lead (Pb), and any alloy thereof.

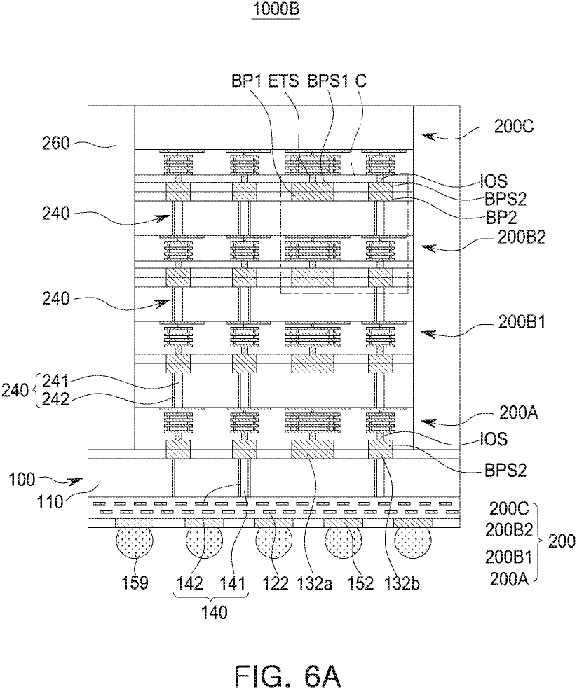

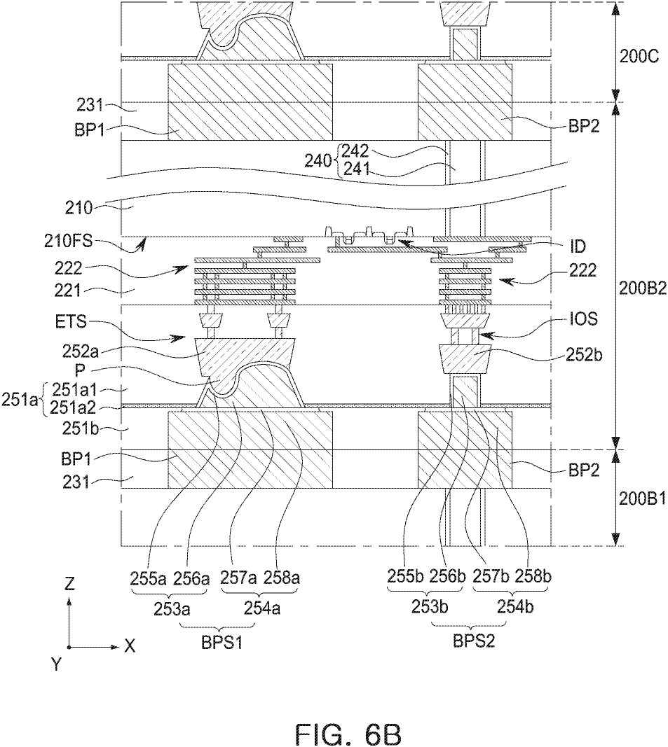

FIG. 6A is a cross-sectional view illustrating a semiconductor package 1000B according to an embodiment of the present inventive concept, and FIG. 6B is an enlarged view illustrating region 'C' of FIG. 6A.

Referring to FIGS. 6A and 6B, the semiconductor package 1000B according to an embodiment of the present inventive concept may have characteristics the same as or similar to those described above with reference to FIGS. 1A to 5B, except that the semiconductor chip 200 on the semiconductor structure 100 is provided as a plurality of semiconductor chips 200A, 200B1, 200B2, and 200C. The semiconductor package 1000B may further include an encapsulant 260 covering the plurality of semiconductor chips 200A, 200B1, 200B2, and 200C on the semiconductor structure 100. The encapsulant 260 may expose an upper surface of the third semiconductor chip 200C, but may also cover the upper surface of the third semiconductor chip 200C according to an embodiment of the present inventive concept. The encapsulant 260 may include, for example, an epoxy mold compound (EMC), but the material of the encapsulant 260 is not particularly limited. The number of the plurality of semiconductor chips 200A, 200B1, 200B2, and 200C is not limited to that illustrated in the drawings and may be two, three, or five or more.

The plurality of semiconductor chips 200A, 200B1, 200B2, and 200C may include a first semiconductor chip 200A attached to an upper surface of the semiconductor structure 100, one or more second semiconductor chips 200B1 and 200B2 sequentially stacked on the first semiconductor chip 200A, and the third semiconductor chip 200C stacked on the second semiconductor chips 200B1 and 200B2. Each of the first to third semiconductor chips 200A, 200B1, 200B2, and 200C may include a first bonding pad structure BPS1 on the electrical test structure ETS and a second bonding pad structure BPS2 on the input/output structure IOS, respectively, and a hybrid bonding structure may be formed between the first semiconductor chip 200A and the semiconductor structure 100, between the first semiconductor chip 200A and the second semiconductor chips 200B 1 and 200B2, and between the second semiconductor chips 200B 1 and 200B2 and the third semiconductor chip 200C. The first semiconductor chip 200A and the second semiconductor chips 200B1 and 200B2 may further include a silicon through-via 240 and rear bonding pads BP1 and BP2. The silicon through-via 240 may include a through-electrode 241 and a barrier film 242. Since the through-electrode 241 and the barrier film 242 have characteristics similar to those of the through-electrode 141 and the barrier layer 142 of FIG. 1B, redundant descriptions thereof are omitted. The rear bonding pads BP1 and BP2 may include a first rear bonding pad BP1 bonded to the first bonding pad structure BPS1 and a second rear bonding pad BP2 bonded to the second bonding pad structure BPS2. The second rear bonding pad BP2 may be electrically connected to the silicon through-via 240 to provide a transmission path for a plurality of input/output signals. For example, the second rear bonding pad BP2 may have a function and characteristics similar to those of the connection pad 132b described with reference to FIG. 1B. Meanwhile, the first rear bonding pad BP1 is a dummy pad that is not used as an input/output signal transmission path, and thus, heat dissipation characteristics of the semiconductor package 1000B may be enhanced by increasing density of a conductive material. For example, the first rear bonding pad BP1 may have a function and characteristics similar to those of the dummy pad 132a described with reference to FIG. 1B. The rear bonding pads BP1 and BP2 may be surrounded by a bonding insulating layer 231 including silicon oxide (SiO₂) or the like. The bonding insulating layer 231 may have a function and characteristics similar to those of the rear insulating layer 131 described with reference to FIG. 1B.

The semiconductor structure 100 may be a buffer chip including a plurality of logic devices and/or memory devices. Accordingly, the semiconductor structure 100 transmits signals from the plurality of semiconductor chips 200A, 200B1, 200B2, and 200C stacked thereon to the outside, and also transmits signals and power from the outside to the plurality of semiconductor chips 200A, 200B1, 200B2, and 200C. The semiconductor structure 100 may perform both a logic function and a memory function through logic elements and memory elements. However, according to an embodiment of the present inventive concept, the semiconductor structure 100 may include only the logic elements to perform only the logic function. The plurality of semiconductor chips 200A, 200B1, 200B2, and 200C may include, for example, volatile memory chips such as DRAM and SRAM, or non-volatile memory chips such as PRAM, MRAM, FeRAM, or RRAM. For example, the semiconductor package 1000B of the present embodiment may be used in a high bandwidth memory (HBM) product, an electro data processing (EDP) product, or the like.

FIG. 7 is a cross-sectional view illustrating a semiconductor package 1000C according to an embodiment of the present inventive concept.

Referring to FIG. 7, the semiconductor package 1000C according to an embodiment of the present inventive concept has characteristics the same as or similar to those described above with reference to FIGS. 1A to 6B, except that the semiconductor package 1000C further includes a package substrate 300 on which the semiconductor structure 100 is mounted and an encapsulant 260 encapsulating the semiconductor structure 100 and the semiconductor chip 200 on the package substrate 300.

In an embodiment of the present inventive concept, the semiconductor structure 100 may be, for example, a logic chip including a central processor (CPU), a graphics processor (GPU), a field programmable gate array (FPGA), an application processor (AP), a digital signal processor (DSP), a cryptographic processor, a microprocessor, a microcontroller, an analog-to-digital converter, an application specific integrated circuit (ASIC), or the like. Also, the semiconductor chip 200 may include a memory chip such as DRAM, SRAM, PRAM, MRAM, FeRAM, or RRAM. When the semiconductor structure 100 is a semiconductor chip (e.g., a logic chip), the semiconductor structure 100 and the semiconductor chip 200 (e.g., a memory chip) stacked thereon may be chiplets constituting a multi-chip module (MCM), but the present inventive concept is not limited thereto. In the present embodiment, the semiconductor chip 200 is illustrated to be the same as that of FIG. 1B, but may have a shape similar to that described above with reference to FIGS. 5A to 6B. For example, the semiconductor chip 200 may include a power management IC (PMIC) chip.

As set forth above, according to an embodiment of the present inventive concept, a semiconductor package having enhanced heat dissipation characteristics by introducing a bonding pad bonded to a dummy pad on a test pad may be provided.

By introducing the bonding pad having a specific crystal direction, a semiconductor package having enhanced bonding reliability of hybrid bonding may be provided.

While embodiments of the present inventive concept have been shown and described above, it will be apparent to those skilled in the art that modifications and variations could be made without departing from the spirit and scope of the present inventive concept as defined by the appended claims.

1. A semiconductor package comprising:
a base structure including a body having a rear surface on which a dummy pad and a connection pad are arranged and a rear insulating layer disposed on the rear surface and surrounding the dummy pad and the connection pad; and
a semiconductor chip disposed on the base structure and including a semiconductor layer having a front surface facing the rear surface of the body, a test pad and an input/output pad disposed on the front surface of the semiconductor layer, a first bonding insulating layer surrounding the test pad and the input/output pad, a first bonding pad structure disposed between the test pad and the dummy pad, a second bonding pad structure disposed between the input/output pad and the connection pad, and a second bonding insulating layer disposed on the first bonding insulating layer and surrounding at least a portion of each of the first bonding pad structure and the second bonding pad structure,
wherein the first bonding pad structure includes a first contact portion being in contact with the test pad inside the first bonding insulating layer and having a lower surface positioned opposite to the test pad, a first bonding pad bonded to the dummy pad, and a first seed layer disposed between the first bonding pad and the first contact portion and extending in a first direction, parallel to the lower surface of the first contact portion,
the second bonding pad structure includes a second contact portion being in contact with the input/output pad inside the first bonding insulating layer and having a lower surface positioned opposite to the input/output pad, a second bonding pad bonded to the connection pad, and a second seed layer disposed between the second bonding pad and the second contact portion and extending in the first direction, and
the second bonding insulating layer is in contact with a side surface of each of the first and second seed layers and the first and second bonding pads.

2. The semiconductor package of claim 1, wherein the lower surface of the first contact portion and the lower surface of the second contact portion are coplanar with each other.

3. The semiconductor package of claim 1, wherein
the first seed layer overlaps the first bonding pad in a second direction, perpendicular to the first direction, and
the second seed layer overlaps the second bonding pad in the second direction.

4. The semiconductor package of claim 1, wherein
the first seed layer has a width equal to or smaller than a width of the first bonding pad, and
the second seed layer has a width equal to or smaller than a width of the second bonding pad.

5. The semiconductor package of claim 1, wherein
the side surface of the first seed layer is spaced apart from the side surface of the first bonding pad, and
the side surface of the second seed layer is spaced apart from the side surface of the second bonding pad.

6. The semiconductor package of claim 1, wherein a width of the first bonding pad is greater than a width of the second bonding pad.

7. The semiconductor package of claim 6, wherein
the width of the first bonding pad is about 30 µm or greater, and
the width of the second bonding pad is about 20 µm or smaller.

8. The semiconductor package of claim 1, wherein
the first and second bonding pads include copper (Cu) or a Cu alloy, and
the test pad and the input/output pad include aluminum (Al) or an Al alloy.

9. The semiconductor package of claim 8, wherein the first and second seed layers include titanium (Ti) or a Ti alloy.

10. (canceled)

11. The semiconductor package of claim 1, wherein the test pad has a protrusion having a pile-up surface.

12. The semiconductor package of claim 1, wherein the base structure further includes:
individual elements disposed on a front surface of the body positioned opposite to the rear surface and a through-via penetrating through the body and electrically connected to the individual elements,
wherein the connection pad is electrically connected to the through-via, and
the dummy pad is electrically insulated from the through-via.

13. The semiconductor package of claim 1, wherein the rear insulating layer and the second bonding insulating layer include silicon oxide or silicon nitride.

14. A semiconductor package comprising:
a base structure including a body having a rear surface on which a dummy pad and a connection pad are arranged and a rear insulating layer disposed on the rear surface and surrounding the dummy pad and the connection pad; and
a semiconductor chip disposed on the base structure and including a semiconductor layer having a front surface facing the rear surface of the body, a test pad and an input/output pad disposed on the front surface of the semiconductor layer, a first bonding pad structure disposed between the test pad and the dummy pad, a second bonding pad structure disposed between the input/output pad and the connection pad, and a bonding insulating layer disposed on the front surface of the semiconductor layer and surrounding at least a portion of each of the first bonding pad structure and the second bonding pad structure,
wherein the first bonding pad structure includes a first contact portion being in contact with the test pad, a first bonding pad bonded to the dummy pad, and a first seed layer extending in a first direction between the first bonding pad and the first contact portion,
the second bonding pad structure includes a second contact portion being in contact with the input/output pad, a second bonding pad bonded to the connection pad, and a second seed layer extending in the first direction between the second bonding pad and the second contact portion,
the first bonding pad includes first grain structures extending in a second direction, perpendicular to the first direction, and
the second bonding pad includes second grain structures extending in the second direction.

15. The semiconductor package of claim 14, wherein the first and second grain structures have a 111 crystal orientation.

16. The semiconductor package of claim 15, wherein at least a portion of the first and second grain structures includes a nanotwin structure.

17. The semiconductor package of claim 14, wherein the first and second grain structures have a width of about 1 µm or smaller in the first direction.

18. The semiconductor package of claim 14, wherein the first and second grain structures have a height of about 0.5 µm or greater in the second direction.

19. A semiconductor package comprising:
a base structure including a body having a rear surface on which a dummy pad is disposed and a rear insulating layer disposed on the rear surface and surrounding the dummy pad; and
a semiconductor chip disposed on the base structure and including a semiconductor layer having a front surface facing the rear surface of the body, a test pad disposed on the front surface of the semiconductor layer, a bonding pad structure disposed between the test pad and the dummy pad, and a bonding insulating layer surrounding at least a portion of the bonding pad structure,
wherein the bonding pad structure includes a contact portion being in contact with the test pad and having a lower surface positioned opposite to the test pad, a bonding pad bonded to the dummy pad, and a seed layer disposed between the bonding pad and the contact portion and extending in a first direction parallel to the lower surface of the contact portion, and
the bonding insulating layer is in direct contact with a side surface of the bonding pad.

20. (canceled)

21. The semiconductor package of claim 19, wherein the seed layer has a width greater than a width of the lower surface of the contact portion and smaller than a width of the bonding pad in the first direction.

22. The semiconductor package of claim 19, wherein at least a portion of the bonding pad does not overlap the seed layer in a second direction, perpendicular to the first direction.

23-30. (canceled)
